(19) United States
(12) Patent Application Publication
(10) Pub. No.: US 2011/0111540 A1
(43) Pub. Date: May 12, 2011

(54) METHOD OF FABRICATING FLAT PANEL DISPLAY

(75) Inventor: HYUN-EOK SHIN, Suwon-si (KR)

(73) Assignee: SAMSUNG MOBILE DISPLAY CO., LTD., Suwon-si (KR)

(21) Appl. No.: 13/007,121

(22) Filed: Jan. 14, 2011

Related U.S. Application Data
(62) Division of application No. 11/980,379, filed on Oct. 31, 2007.

(30) Foreign Application Priority Data
Nov. 1, 2006 (KR) 10-2006-0107390

(51) Int. Cl. H01L 51/56

(52) U.S. Cl. 438/29; 257/E51.018

(57) ABSTRACT

Exemplary embodiments provide a flat panel display and method for forming the same including a substrate having a pixel driving circuit region and an emission region, a thin film transistor in the pixel driving circuit region, and a pixel electrode on the same layer as the source and drain electrodes. The thin film transistor may include a semiconductor layer, a gate electrode, and source and drain electrodes. The pixel electrode may contact one end of the semiconductor layer of the thin film transistor. The source and drain electrodes and the pixel electrode may be stacked structures having a first metal layer, a second metal layer, and a transparent conductive layer.

### CROSS REFERENCE TO RELATED APPLICATION

This is a divisional application based on pending application Ser. No. 11/980,379, filed Oct. 31, 2007, the entire contents of which is hereby incorporated by reference.

### BACKGROUND OF THE INVENTION

1. Field of Art

Exemplary embodiments relate to a display and a method of fabricating the same, and more particularly, example embodiments relate to an organic light emitting display and a method of fabricating the same.

2. Description of the Related Art

Generally, an organic light emitting display is an emissive display device that emits light by electrically exciting a fluorescent organic compound. The organic light emitting diode (OLED) display may be classified as a passive matrix OLED display or an active matrix OLED display depending on a manner of driving N×M pixels disposed in a matrix. In comparing the active matrix OLED display to the passive matrix OLED display, the active matrix OLED may have the advantage of reducing power consumption, implementing large-sized image display, and providing high resolution.

FIG. 1 illustrates a schematic plan view of a conventional active matrix OLED display, which illustrates an area of a unit pixel region.

Referring to FIG. 1, the unit pixel region may include a scan line 125 disposed in one direction, a data line 135 insulated from the scan line 125 and intersecting the scan line 125, and a common power line 131 insulated from the scan line 125 in a crossing manner and parallel to the data line 135.

Each unit pixel region may include a switching thin film transistor 140 for switching a data signal supplied to the data line 135 in response to a signal supplied to the scan line 125, a capacitor 145 for maintaining the data signal supplied from the switching thin film transistor 140 for a particular amount of time, and a pixel drive thin film transistor 150 for supplying current to a pixel electrode 170 in response to the data signal supplied from the switching thin film transistor 140. An emission layer (not shown) may be on the pixel electrode 170, and an opposite electrode (not shown) may be on the emission layer. The pixel electrode 170, the emission layer and the opposite electrode may form an OLED.

FIG. 2 illustrates a cross-sectional view taken along line I-I′ of FIG. 1, which illustrates a method of fabricating a conventional OLED.

Referring to FIG. 2, a buffer layer 105 may be on a substrate 100, and a semiconductor layer 110 may be on the buffer layer 105. The semiconductor layer 110 may be formed using a first mask. A gate insulating layer 115 may be on the entire surface of the substrate including the semiconductor layer 110, and a gate electrode 120 may be on the gate insulating layer 115. The gate electrode 120 may be formed using a second mask.

An interlayer insulating layer 125 may be on the entire surface of the substrate including the gate electrode 120, and source and drain contact holes 125a exposing both ends of the semiconductor layer 110 may be formed in the interlayer insulating layer 125. Source and drain electrodes 130a may then be formed on the interlayer insulating layer 125 using a fourth mask. The source and drain electrodes 130a may be connected to both ends of the semiconductor layer 110 through the source and drain contact holes 125a.

The source and drain electrodes 130a may be formed of a metal layer. The metal layer may be a single layer made from Mo, W, MoW, AlNd, Ti, Al, an Al alloy, or the like; or a multi-layer made from MoW, Al, an Al alloy, or the like. Even further, the metal layer may be a triple layer formed in a stacked structure, such as, Mo/Al/Mo, MoW/Al/Mo, MoW/Al—Nd/MoW and Ti/Al/Ti. The metal layer may be a low resistance material for reducing interconnection resistance.

A via-hole insulating layer 160 may be on the entire surface of the substrate, which may include the source and drain electrodes 130a, and a via-hole 160a exposing one of the source and drain electrodes 130a may be formed in the via-hole insulating layer 160 by utilizing a fifth mask. Then, a pixel electrode 170 may be formed on the via-hole insulating layer 160 by utilizing a sixth mask. The pixel electrode 170 may be connected to the source and drain electrode 130a, which may be exposed through the via-hole 160a. Subsequently, a pixel defining layer 175 may be formed to cover the pixel electrode 170, and an opening 175a for the pixel electrode 170 may be formed in the pixel defining layer 175 by utilizing a seventh mask.

Continuously, an organic emission layer 200 may be formed on the entire surface of the substrate including the pixel electrode 170 exposed in the opening 175a, and an opposite electrode 220 may be formed on the organic emission layer 200. Therefore, a complete structure of an OLED may be formed.

In accordance with the conventional OLED display, seven masks are typically needed to manufacture the OLED display. Moreover, the conventional OLED requires the additional process of forming a via-hole for connecting the pixel electrode 170 and the source and drain electrodes 130a, and the process of forming a via-hole insulating layer in which the via-hole is disposed. As a result, this increases manufacturing cost of the masks, which may complicate the processes, and increase production cost.

In order to solve the problems related in the conventional art, an OLED display fabricated by forming source and drain electrodes and a pixel electrode on the same plane using five masks has been proposed. However, since the source and drain electrodes and the pixel electrode of the OLED using the five masks are formed on the same plane, in order to simplify the process, the source and drain electrodes should be formed of the same material as the pixel electrode.

Further, when the material for the source and drain electrodes is composed as a stacked structure, such as, Mo/Al/Mo, MoW/Al/Mo, MoW/Al—Nd/MoW and Ti/Al/Ti, which utilizes seven masks, these materials are not compatible for the pixel electrode. Even further, when a Ti/Al/Ti structure is used for the source and drain electrodes, it may be undesirable to use the Ti/Al/Ti structure for the pixel electrode. For instance, when the pixel electrode is employed as an anode electrode, the upper layer, which may be made from Ti, cannot perform the function of an anode electrode. In addition, because Ti has a low reflectivity of, e.g., about 50%, it cannot properly reflect light emitted from the emission layer. Thus, the pixel electrode cannot properly function as a reflective electrode.

### SUMMARY OF THE INVENTION

Exemplary embodiments are therefore directed to display apparatus, which substantially overcomes one or more of the problems due to the limitations and disadvantages of the related art.

It is therefore a feature of exemplary embodiments to provide an OLED display and method of fabricating the same to reduce the number of masks required for fabricating the OLED display.

It is therefore another feature of exemplary embodiments to provide an OLED display and method of fabricating the same to simplify the fabrication process.

It is therefore yet another feature of exemplary embodiments to provide an OLED display and method of fabricating the same to use the same material for interconnection electrodes, such as, source and drain electrodes and a pixel electrode in the OLED.

At least one of the above and other features and advantages of exemplary embodiments may be to provide a flat panel display including a substrate having a pixel driving circuit region and an emission region, a thin film transistor in the pixel driving circuit region, and a pixel electrode on the same layer as the source and drain electrodes. The thin film transistor may include a semiconductor layer, a gate electrode, and source and drain electrodes. The pixel electrode may contact one end of the semiconductor layer of the thin film transistor. The source and drain electrodes and the pixel electrode may be stacked structures having a first metal layer, a second metal layer, and a transparent conductive layer.

At least one of the above and other features and advantages of exemplary embodiments may be to provide a method of fabricating a flat panel display. The method may include providing a substrate having a pixel driving circuit region and an emission region, forming a thin film transistor in the pixel driving circuit region, and forming a pixel electrode on the same layer as the source and drain electrodes. The method may further include the thin film transistor with a semiconductor layer, a gate electrode, and source and drain electrodes. The pixel electrode may contact one end of the semiconductor layer of the thin film transistor. The source and drain electrodes and the pixel electrode may be stacked structures having a first metal layer, a second metal layer, and a transparent conductive layer.

At least one of the above and other features and advantages of exemplary embodiments may be to provide a method of fabricating a flat panel display. The method may include providing a substrate having a pixel driving circuit region and an emission region, forming a semiconductor layer in the pixel driving circuit region on the substrate, forming a gate insulating layer covering the semiconductor layer, depositing a gate electrode material on the gate insulating layer, patterning the gate electrode material and forming a gate electrode on the semiconductor layer, forming an interlayer insulating layer covering the gate electrode, forming first and second source and drain contact holes which may expose ends of the semiconductor layer in the interlayer insulating layer and the gate insulating layer, respectively, forming a pixel electrode material on the substrate including the contact holes, patterning the pixel electrode material to form a pixel electrode which may be disposed on the interlayer insulating layer of the emission region and extends onto the interlayer insulating layer of the pixel driving circuit region, the pixel electrode contacts one end of the semiconductor layer through the first source and drain contact hole, and forming source and drain electrodes which contacts the other end of the semiconductor layer through the second source and drain contact hole. The source and drain electrodes and the pixel electrode may be stacked structures having a first metal layer, a second metal layer and a transparent conductive layer.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a plan view of an active matrix organic light emitting display;

FIG. 2 illustrates a cross-sectional view taken along line I-I′ of FIG. 1, illustrating a method of fabricating an organic light emitting display;

FIG. 3 illustrates a plan view of an organic light emitting display in accordance with exemplary embodiments;

FIGS. 4A and 4B illustrate cross-sectional views taken along line I-I′ of FIG. 3, of a method of fabricating an organic light emitting display in accordance with exemplary embodiments;

FIGS. 5A and 5B illustrate cross-sectional views taken along line II-II′ of FIG. 3, of a method of fabricating an organic light emitting display in accordance with exemplary embodiments; and

FIG. 6 illustrates a graph of reflectivity properties according to a structure of a pixel electrode.

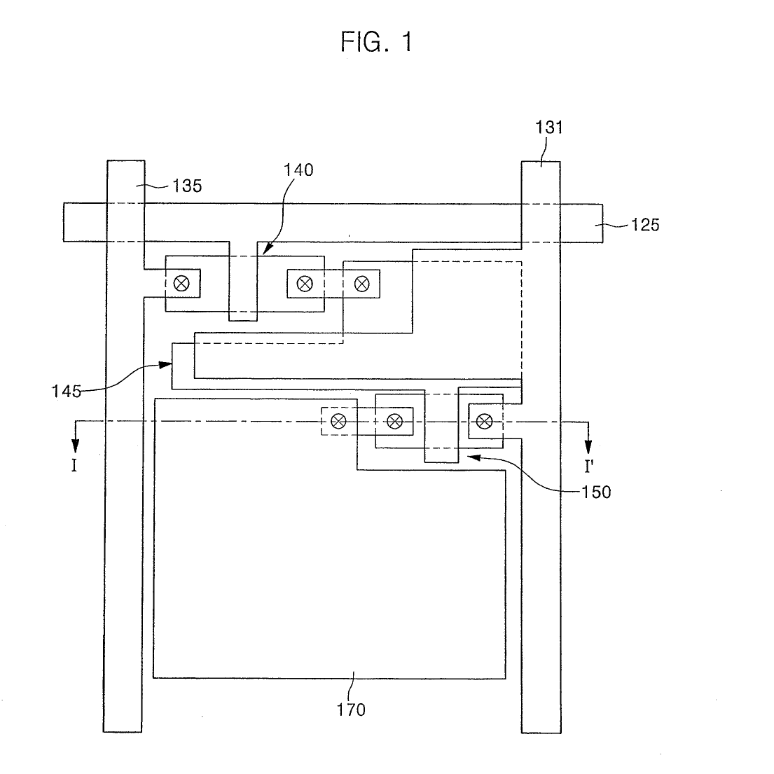

### DETAILED DESCRIPTION OF THE INVENTION

Korean Patent Application No. 2006-107390, filed on Nov. 1, 2006, in the Korean Intellectual Property Office, and entitled: “Flat Panel Display and Method of Fabricating the Same,” is incorporated by reference herein in its entirety.

Exemplary embodiments will now be described more fully hereinafter with reference to the accompanying drawings. The invention may, however, be embodied in different forms and should not be construed as limited to the embodiments set forth herein. Rather, these exemplary embodiments are provided so that this disclosure will be thorough and complete, and will fully convey the scope of the invention to those skilled in the art.

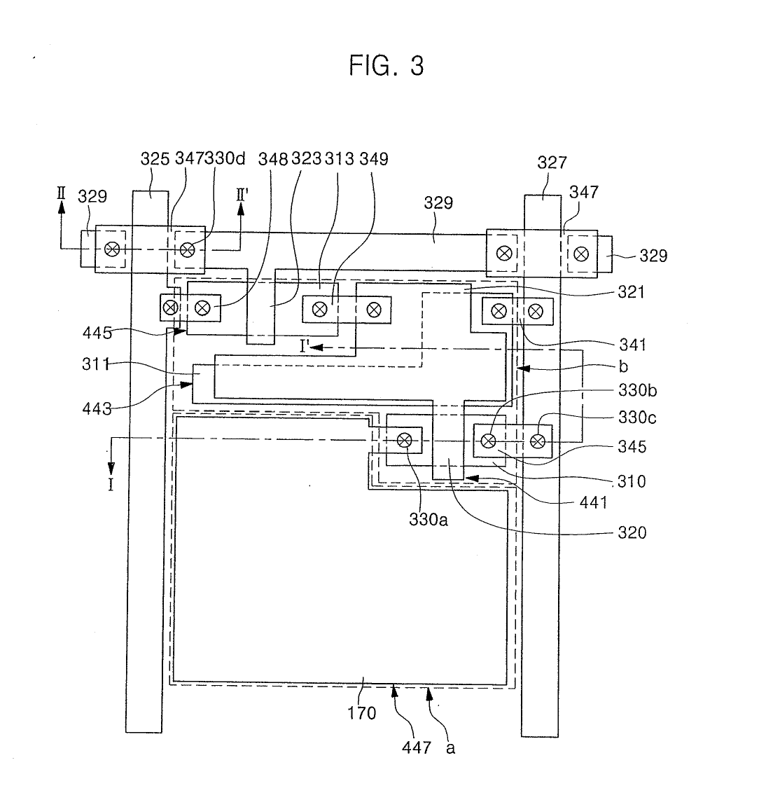

FIG. 3 illustrates a plan view of an OLED display in accordance with exemplary embodiments, illustrating an area of a unit pixel region.

Referring to FIG. 3, a unit pixel region may be defined by signal lines disposed in a matrix on a substrate. The signal lines may include a data line 325 disposed in one direction, a common power line 327 separated from the data line 325 by a distance and parallel to the data line 325, and a scan line intersecting the data line 325 and the common power line 327. The scan line may include, at the section interconnecting the data line 325 and/or the common power line 327, scan line patterns 329 disposed at both sides of the data line 325 and/or the common power line 327. The scan line patterns 329 may be parallel to and separated from each other. The scan line may select a unit pixel to be driven, and the data line 325 may apply a voltage to the selected unit pixel. Further, an interconnection 347 may be in contact with the scan line patterns 329 through interconnection contact holes 330d and insulated from the data line 325 and/or the common power line 327.

The unit pixel region may be divided into an emission region (a) and a pixel driving circuit region (b). An OLED diode 447 may be positioned at the emission region (a). The pixel driving circuit region (b) may include a switching thin film transistor 445 for switching a data signal supplied to the data line 325 in response to a signal supplied to the scan line, a capacitor 443 for maintaining the data signal supplied from the switching thin film transistor 445 for a particular amount of time, and a pixel driving thin film transistor 441 for applying current to the organic light emitting diode 447 in response to the data signal supplied from the switching thin film transistor 445.

The OLED 447 may include a pixel electrode 350, an organic functional layer (not shown) including an organic emission layer disposed on the pixel electrode 350, and an opposite electrode (not shown). The pixel driving thin film transistor 441 may include a semiconductor layer 310, a gate electrode 320, and source and drain electrodes 345. The pixel electrode 350 may extend to the pixel driving circuit region, which may be in contact with one end of the semiconductor layer 310 through a first source and drain contact hole 330a. Further, the source and drain electrodes 345 may be in contact with the common power line 327 through a connection contact hole 330c, and jointly, in contact with the other end of the semiconductor layer 310 through a second source and drain contact hole 330b.

The capacitor 443 may include an upper electrode 321 and a lower electrode 311 which may be connected to a gate electrode 320 of the pixel driving thin film transistor 441. The lower electrode 311 may be electrically connected to the common power line 327 by contact holes and a capacitor interconnection 341. The switching thin film transistor 445 may include a gate electrode 323 connected to the scan line, a semiconductor layer 313, source and drain electrodes 349 in contact with the upper electrode 321 of the capacitor 443 and one end of the semiconductor layer 313 through contact holes, respectively, and source and drain electrodes 348 in contact with the data line 325 and the other end of the semiconductor layer 313 through contact holes, respectively.

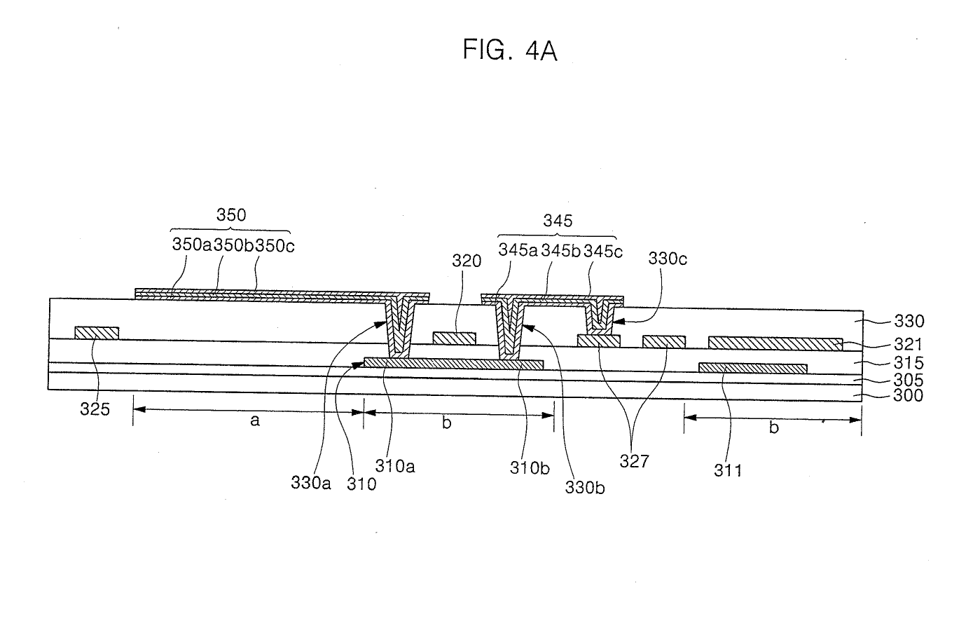

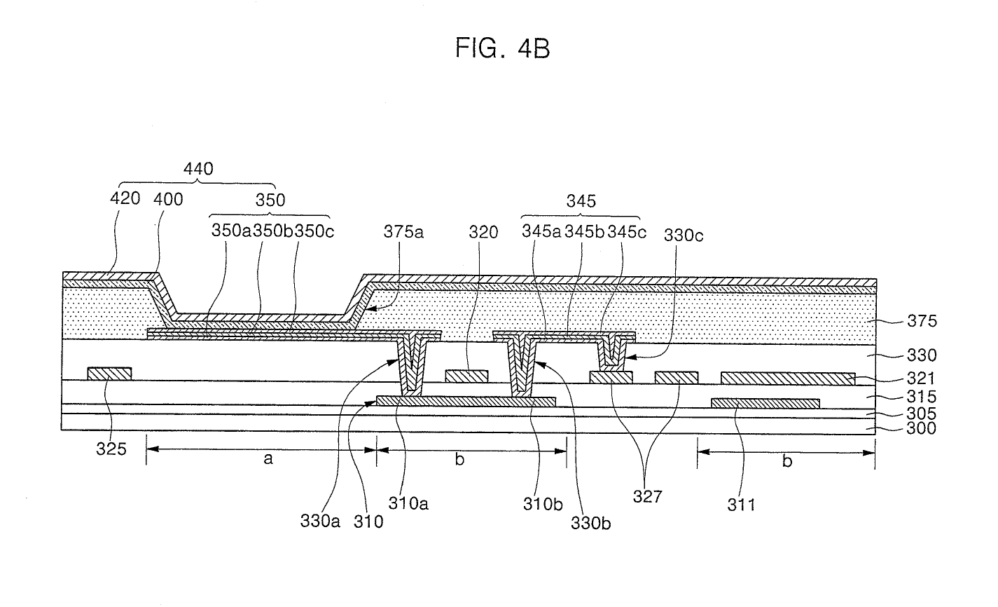

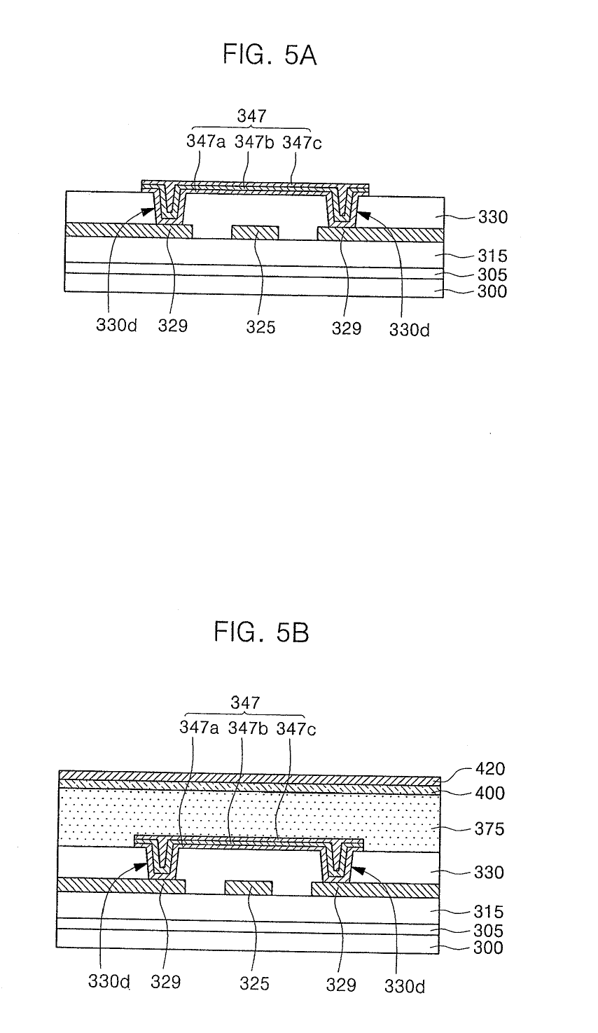

FIGS. 4A and 4B illustrate cross-sectional views taken along line I-I′ of FIG. 3, and FIGS. 5A and 5B illustrate cross-sectional views taken along line II-II′ of FIG. 3, of a method of fabricating an OLED display in accordance with exemplary embodiments.

Referring to FIGS. 4A and 5A, a substrate 300 may have the emission region (a), the pixel driving circuit region (b), and an interconnection region, except the regions (a) and (b) is provided. The substrate 300 may be formed of, for example, but not limited to, glass and/or plastic. A buffer layer 305 may be formed on the substrate 300. The buffer layer 305 may function to protect a thin film transistor from forming impurities, such as, alkali ions discharged from the substrate 300, which may be formed of a silicon oxide layer and/or a silicon nitride layer, for example.

An amorphous silicon layer may be deposited on the buffer layer 305 of the pixel driving circuit region (b), and then crystallized to form a polysilicon layer, for example. The polysilicon layer may be patterned using a first mask to form a semiconductor layer 310 having ends 310a and 310b, and the lower electrode 311. A gate insulating layer 315 may then be formed on the entire or substantially entire surface of the substrate 300 including the semiconductor layer 310 and the lower electrode 311. Crystallizing the amorphous silicon layer may be performed using at least one of an excimer laser annealing (ELA) method, a sequential lateral solidification (SLS) method, a metal induced crystallization (MIC) method, and a metal induced lateral crystallization (MILC) method. It should be appreciated by one skilled in the art that other methods may be performed to crystallize the amorphous silicon layer.

A gate electrode material may then be deposited on the gate insulating layer 315, and patterned using a second mask. Accordingly, a gate electrode 320 corresponding to a portion of the semiconductor layer 310 may be formed. Further, while forming the gate electrode 320, the upper electrode 321 corresponding to the lower electrode 311 may be formed, and the data line 325, the common power line 327, and the scan line pattern 329 may be formed on the interconnection region. The gate electrode material may be one selected from at least one of an Al, an Al alloy, a Mo, and a Mo alloy. It should further be appreciated that the gate electrode material may be a Mo—W alloy.

An interlayer insulating layer 330 may then be formed to cover the gate electrode 320, the upper electrode 321, the data line 325, the common power line 327, and the scan line pattern 329. The interlayer insulating layer 330 may be formed of at least one of an organic layer, an inorganic layer, and an organic-inorganic composite layer. Forming the interlayer insulating layer 330 of an organic-inorganic composite layer may be performed by depositing an organic layer on an inorganic layer, for example. The organic layer may be a benzocyclobutene (BCB) layer, for example, and the inorganic layer may be a silicon oxide layer or a silicon nitride layer, for example. It should be appreciated that other materials and methods may be employed to form the interlayer insulating layer 330.

The first source and drain contact hole 330a and the second source and drain contact hole 330b, which may expose ends 310a and 310b of the semiconductor layer 310, may be formed in the interlayer insulating layer 330 and the gate insulating layer 315 using a third mask. Further, the connection contact hole 330c, exposing the common power line 327 of the interconnection region and interconnection contact holes 330d exposing the scan line patterns 329 disposed at both sides of the data line 325, may be formed in the interlayer insulating layer 330.

A pixel electrode material may then be deposited on the substrate, where the contact holes 330a, 330b, 330c and 330d are formed, and patterned using a fourth mask. Accordingly, at this stage, the pixel electrode 350, source and drain electrodes 345, and the interconnection 347 may be formed. The pixel electrode 350 may be formed on the interlayer insulating layer 330 of the emission region (a), and may extend to the pixel driving circuit region (b), which may be in contact with one end 310a of the semiconductor layer 310 through the first source and drain contact hole 330a. The source and drain electrodes 345 may be formed on the interlayer insulating layer 330 of the pixel driving circuit region (b) so as to be in contact with the other end 310b of the semiconductor layer 310 through the second source and drain contact hole 330b, while at the same time, extend to the interconnection region so as to be in contact with the common power line 327 through the connection contact hole 330c. As a result, the pixel driving thin film transistor 441 may include the semiconductor layer 310, the gate electrode 320, and the pixel electrode 350 and the source and drain electrodes 345 of the pixel driving circuit region (b).

The interconnection 347 may then be disposed on the interlayer insulating layer 330 of the interconnection region, insulated from the data line 325, and in contact with the scan line patterns 329 through the interconnection contact holes 330c.

Accordingly, the pixel electrode 350, the source and drain electrodes 345, and the interconnections 347 may be formed in a stacked structure of first metal layers 350a, 345a or 347a, second metal layers 350b, 345b or 347b, and transparent conductive layers 350c, 345c or 347c, respectively. The first metal layers, the second metal layers, and the transparent conductive layers may be sequentially formed by, for example, but not limited to, a sputtering method. It should be appreciated that other methods may be employed.

The first metal layer may be formed of, for example, but not limited to, Ti and/or Al. These materials generally provide good adhesion to the interlayer insulating layer 330. The second metal layer (e.g., as a metal layer for reflecting light) may be formed of, for example, but not limited to, an Al—Ni alloy, i.e., ACX, which may provide good reflectivity. The Al—Ni alloy used for the second metal layer may contain Ni of approximately 3-10%. In addition, the transparent conductive layer may be formed of ITO and/or IZO, generally ITO, for example.

Further, the pixel electrode 350, the source and drain electrodes 345, and the interconnection 347 may be patterned by continuously performing a photolithography process and/or an etching process, for example. For instance, a photoresist pattern may be formed on the transparent conductive layer, and then subjected to general exposure and development processes. The first metal layer, the second metal layer and the transparent conductive layer may then be sequentially etched using the photoresist pattern as a mask.

The etching process may generally be a wet etching method or a dry etching method, for example. In the case of a wet etching method, a strong acidic solution, such as, but not limited to, HF, HNO3, and/or H2SO4, may be applied or injected onto a region to be etched so as to obtain a desired pattern. Further, strong acidic and strong alkaline chemicals, such as, but not limited to, HNO3, HCL, H3PO4, H2O2, and/or NH4OH, may also be used during a cleaning process and a strip process after the etching.

As a result of direct contact of the strong acidic and alkaline chemicals used in the etching, cleaning, and/or stripping processes with the second metal layer and the transparent conductive layer, in which each layer is formed in accordance with a different function, galvanic corrosion may be produced at the interface between the second metal layer and the transparent conductive layer.

In order to suppress the galvanic corrosion, the second metal layer may be composed of an Al—Ni alloy, (e.g., ACX), which may contain Ni of approximately 3-10%.

Further, reduction and oxidation (redox) potential of pure aluminum may be approximately −1.64, and redox potential of ITO, which may be widely used as a pixel electrode material, may be approximately −0.82. Therefore, because the difference between redox potentials of Al and ITO is substantial, the second metal layer may be formed of an Al—Ni alloy (e.g., ACX). Further, when the content of Ni in the Al—Ni alloy is approximately 3%, the redox potential may be −1.02. In this case, because the difference between the redox potentials is 0.2, it may be possible to suppress the galvanic corrosion. On the other hand, when content of Ni in the Al—Ni alloy is less than 3% due to the difference between the redox potentials being more than 0.2, it may be difficult to effectively suppress the galvanic corrosion. In addition, the more the content of Ni, the less the difference between the redox potentials of the second metal layer and the transparent conductive layer. However, when the content of Ni is more than 10% contained in pure aluminum, which may include a specific resistance 2.74 μΩ·cm to form the alloy, a specific resistance of the second metal layer may exceed 4.0 μΩ·cm. This results in being not appropriate as a material for the interconnection. Therefore, content of Ni in the Al—Ni alloy may be within a range of approximately 3-10%.

Moreover, because the Al—Ni alloy used for the second metal layer may have a property of high reflectivity, it may be appropriate as a reflective electrode of an anode electrode. Further, because the transparent conductive layer formed on the second metal layer has good transmittance properties, it may be appropriate as a material for the pixel electrode.

As described above, exemplary embodiments provide the pixel electrode 350, the source and drain electrodes 345, and the interconnection 347 as a stacked structure. The stacked structure may include the first metal layer, the second metal layer and the transparent conductive layer. The first metal layer may be formed of Ti and/or Al, for example, the second metal layer may be formed of an Al—Ni alloy containing Ni of approximately 3-10%, for example, and the transparent conductive layer may be formed of ITO and/or IZO, for example. As a result, because the first metal layer may enhance adhesion to the interlayer insulating layer 330, and the second metal layer may decrease the resistance characteristics of the interconnection, it may be possible to fabricate an OLED using five masks that can be used as a low resistance electrode.

Further, because the first metal layer may enhance adhesion to the interlayer insulating layer 330, and the second metal layer and/or the transparent conductive layer may increase the reflectivity characteristics of the pixel electrode, it may be possible to provide an OLED display which uses five masks and/or suppress galvanic corrosion to the transparent conductive layer. This may result in the fabrication of an OLED display using a material appropriate to all of the interconnection electrode, such as, but not limited to, the source and drain electrodes and the pixel electrode.

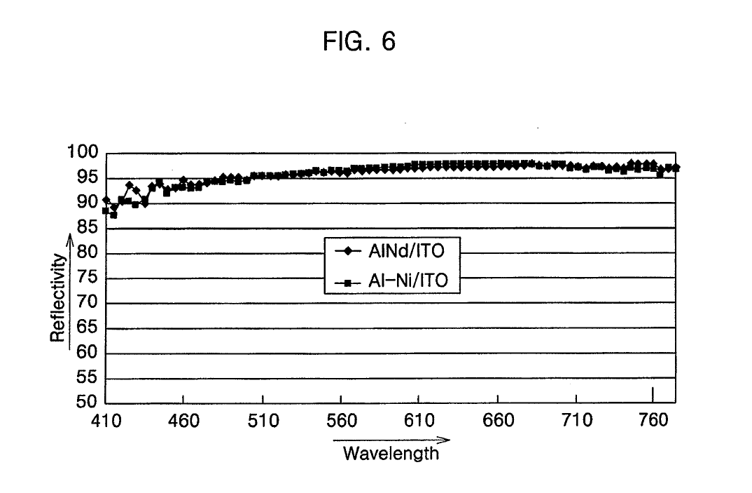

FIG. 6 illustrates a graph of reflectivity properties according to the structure of a pixel electrode.

Referring to FIG. 6, it will be appreciated that reflectivity in the case of applying AlNd/ITO as the pixel electrode of the OLED may be similar to that in the case of applying Al—Ni/ITO. That is, it will be appreciated that there may not be any influence to reflectivity of the pixel electrode, even though Al—Ni may be used as a reflective layer of the pixel electrode of a top emission OLED.

Referring back to FIGS. 4B and 5B, a pixel defining layer 375 may be formed to cover the pixel electrode 350, the source and drain electrodes 345, and the interconnection 347. The pixel defining layer 375 may be formed of one selected from at least one of a benzocyclobutene (BCB), an acryl-based polymer, and a polyimide. It should be appreciated that other materials may be employed to form the pixel defining layer 375.

An opening 375a may then be formed in the pixel defining layer 375 using a fifth mask to expose the pixel electrode 350 of the emission region (a). An organic layer 400 including an organic emission layer may then be formed on the pixel electrode 350 exposed in the opening 375a. The organic layer 400 may be selected from at least one of a hole injection layer (HIL), a hole transport layer (HTL), a hole blocking layer (HBL), an electron transport layer (ETL), and an electron injection layer (EIL). An opposite layer 420 may be formed on the organic layer 400. As a result, an OLED may be formed including the pixel electrode 350, the opposite electrode 420, and the organic layer 400 interposed therebetween.

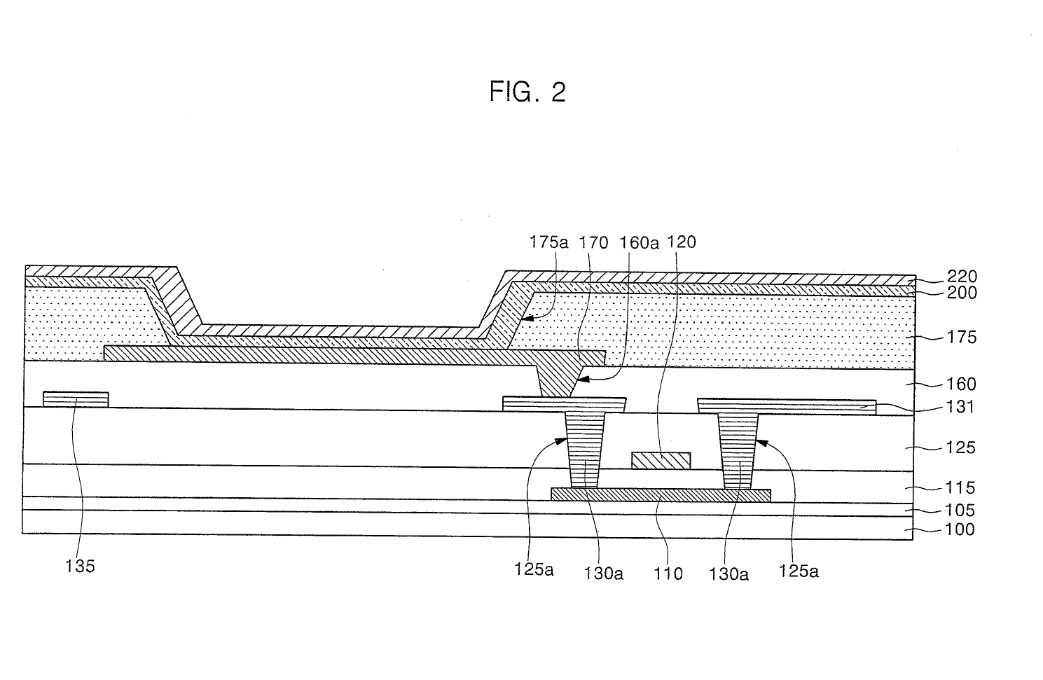

As described above, the OLED display may be fabricated using five masks in exemplary embodiments. Further, the pixel electrode 350 may be in direct contact with the semiconductor layer 310 of the pixel driving thin film transistor via the first source and drain contact hole 330a. As a result, this may eliminate the additional processes of forming a via-hole 160a (see FIG. 2) and forming a via-hole insulating layer 160 in which the via-hole 160a is disposed.

As can be seen from the foregoing, it may be possible to obtain a display capable of reducing the number of masks required for fabricating the display, and eliminating the additional processes of forming a via-hole electrically connecting a pixel electrode and a pixel driving thin film transistor and forming a via-hole insulating layer in which the via-hole is disposed.

Moreover, the pixel electrode 350, the source and drain electrodes 345, and the interconnection 347 may be formed as a stacked structure, such as, a first metal layer/a second metal layer/a transparent conductive layer. The first metal layer may be formed of Ti and/or Al, for example, the second metal layer may be formed of an Ai-Ni alloy containing Ni of approximately 3-10%, for example, and the transparent conductive layer may be formed of ITO and/or IZO, for example. As a result, it may be possible to fabricate an OLED display using a material appropriate to all of the interconnection electrode, such as, but not limited to, the source and drain electrodes and the pixel electrode.

In the figures, the dimensions of layers and regions may be exaggerated for clarity of illustration. It will also be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Further, it will be understood that when a layer is referred to as being “under” or “above” another layer, it can be directly under or directly above, and one or more intervening layers may also be present. In addition, it will also be understood that when a layer is referred to as being “between” two layers, it can be the only layer between the two layers, or one or more intervening layers may also be present. Like numbers refer to like elements throughout. As used herein, the term “and/or” includes any and all combinations of one or more of the associated listed items.

It will also be understood that, although the terms “first” and “second” etc. may be used herein to describe various elements, structures, components, regions, layers and/or sections, these elements, structures, components, regions, layers and/or sections should not be limited by these terms. These terms are only used to distinguish one element, structure, component, region, layer and/or section from another element, structure, component, region, layer and/or section. Thus, a first element, structure, component, region, layer or section discussed below could be termed a second element, structure, component, region, layer or section without departing from the teachings of exemplary embodiments.

Spatially relative terms, such as “beneath,” “below,” “lower,” “above,” “upper” and the like, may be used herein for ease of description to describe one element or feature relationship to another element(s) or feature(s) as illustrated in the figures. It will be understood that the spatially relative terms are intended to encompass different orientations of the device in use or operation in addition to the orientation depicted in the figures. For example, if the device in the figures is turned over (or upside down), elements or layers described as “below” or “beneath” other elements or layers would then be oriented “above” the other elements or layers. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized embodiments (and intermediate structures) of exemplary embodiments. As such, variations from the shapes of the illustrations as a result, for exemplary, of manufacturing techniques and/or tolerances, are to be expected. Thus, exemplary embodiments should not be construed as limited to the particular shapes of regions illustrated herein but are to include deviations in shapes that result, for exemplary, from manufacturing. For exemplary, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1.-15. (canceled)

16. A method of fabricating a flat panel display, comprising:
providing a substrate having a pixel driving circuit region and an emission region;
forming a semiconductor layer in the pixel driving circuit region on the substrate;
forming a gate insulating layer covering the semiconductor layer;
depositing a gate electrode material on the gate insulating layer, patterning the gate electrode material, and forming a gate electrode on the semiconductor layer;
forming an interlayer insulating layer covering the gate electrode;
forming first and second source and drain contact holes exposing ends of the semiconductor layer in the interlayer insulating layer and the gate insulating layer, respectively;
forming a pixel electrode material on the substrate including the contact holes;
patterning the pixel electrode material to form a pixel electrode which is disposed on the interlayer insulating layer of the emission region and extends onto the interlayer insulating layer of the pixel driving circuit region, the pixel electrode contacts one end of the semiconductor layer through the first source and drain contact hole; and
forming source and drain electrodes which contacts the other end of the semiconductor layer through the second source and drain contact hole,
wherein the source and drain electrodes and the pixel electrode are stacked structures having a first metal layer, a second metal layer and a transparent conductive layer.

17. A method of fabricating a flat panel display, comprising:
providing a substrate having a pixel driving circuit region and an emission region;
forming a thin film transistor in the pixel driving circuit region, the thin film transistor including a semiconductor layer, a gate electrode, and source and drain electrodes; and
forming a pixel electrode on the same layer as the source and drain electrodes, the pixel electrode contacting one end of the semiconductor layer of the thin film transistor, wherein the source and drain electrodes and the pixel electrode are stacked structures having a first metal layer, a second metal layer, and a transparent conductive layer.

18. The method as claimed in claim 17, wherein the pixel electrode is in the emission region.

19. The method as claimed in claim 17, further comprising:
forming an organic layer on the pixel electrode, the organic layer including an organic emission layer; and
forming an opposite electrode on the organic layer.
